(19) United States
(12) Patent Application Publication
(10) Pub. No.: US 2024/0099000 A1
(43) Pub. Date: Mar. 21, 2024

(54) SEMICONDUCTOR MEMORY DEVICE AND METHOD OF MANUFACTURING SEMICONDUCTOR DEVICE

(71) Applicant: Kioxia Corporation, Tokyo (JP)

(72) Inventor: Kotaro NOMURA, Yokkaichi (JP)

(73) Assignee: Kioxia Corporation, Tokyo (JP)

(21) Appl. No.: 18/458,284

(22) Filed: Aug. 30, 2023

(30) Foreign Application Priority Data
Sep. 20, 2022 (JP) 2022-149481

(51) Int. Cl. H10B 43/27

(52) U.S. Cl. CPC H10B 43/27; H10B 43/10

(57) ABSTRACT

A semiconductor memory device of an embodiment includes a first region having a first stack and a first pillar, and a second region having a second stack and a second pillar. The first stack comprises an alternate stack in a first direction of a plurality of first insulating films containing oxygen and a plurality of first conductive films. The first pillar comprises a semiconductor layer and extends in the first direction within the first stack. The second stack comprises a repeated stack in the first direction of the plurality of first insulating films, a plurality of second insulating films, and a plurality of third insulating films in the order of the first insulating film, the second insulating film, and the third insulating film. The second insulating film contains nitrogen. The third insulating film contains nitrogen and at least one of oxygen and hydrogen. The second pillar comprises a semiconductor layer and extends in the first direction within the second stack. The first region and the second region are adjacent to each other in a second direction intersecting the first direction.

### CROSS-REFERENCE TO RELATED APPLICATIONS

This application is based upon and claims the benefit of priority from Japanese Patent Application No. 2022-149481, filed Sep. 20, 2022, the entire contents of which are incorporated herein by reference.

### BACKGROUND

### Field

Embodiments described herein relate to a semiconductor memory device and a method of manufacturing a semiconductor device.

### Related Art

A semiconductor memory device may include a substrate, a plurality of wiring layers at multi-levels in a first direction vertical to a surface of the substrate, and a pillar extending in the first direction through the plurality of wiring layers.

### BRIEF DESCRIPTION OF THE DRAWINGS

FIG. 1 is a block diagram illustrating a semiconductor memory device and a memory controller of an embodiment.

FIG. 2 is a diagram illustrating an equivalent circuit of a portion of a memory cell array of the semiconductor memory device of the embodiment.

FIG. 3 is a plan view illustrating a portion of the semiconductor memory device of the embodiment.

FIG. 4 is a cross-sectional view illustrating a portion of the semiconductor memory device of the embodiment.

FIG. 5A is a cross-sectional view illustrating a first pillar of the semiconductor memory device of the embodiment and its vicinity.

FIG. 5B is a cross-sectional view illustrating a second pillar of the semiconductor memory device of the embodiment and its vicinity.

FIG. 5C is a cross-sectional view illustrating a modification example of the first pillar of the semiconductor memory device of the embodiment and its vicinity.

FIG. 6 is a cross-sectional view illustrating the first pillar of the semiconductor memory device of the embodiment and its vicinity.

FIG. 7 is an enlarged cross-sectional view of the vicinity of a conductive film of the semiconductor memory device of the embodiment.

FIG. 8A is a cross-sectional view illustrating a method of manufacturing the semiconductor memory device of the embodiment.

FIG. 8B is a cross-sectional view illustrating a method of manufacturing the semiconductor memory device of the embodiment.

FIG. 9 is a cross-sectional view illustrating a method of manufacturing the semiconductor memory device of the embodiment.

FIG. 10 is a cross-sectional view illustrating a method of manufacturing the semiconductor memory device of the embodiment.

FIG. 11 is a cross-sectional view illustrating a method of manufacturing the semiconductor memory device of the embodiment.

FIG. 12 is a cross-sectional view illustrating a portion of a semiconductor memory device of a modification example of the embodiment.

FIG. 13A is a cross-sectional view illustrating a method of manufacturing the semiconductor memory device of the modification example of the embodiment.

FIG. 13B is a cross-sectional view illustrating a method of manufacturing the semiconductor memory device of the modification example of the embodiment.

FIG. 14A is a cross-sectional view illustrating the vicinity of a memory hole during formation of the memory hole in a method of manufacturing a semiconductor memory device of a comparative example.

FIG. 14B is a cross-sectional view illustrating the vicinity of a memory hole during formation of the memory hole in the method of manufacturing the semiconductor memory device of the embodiment.

### DETAILED DESCRIPTION

Hereinafter, a semiconductor memory device of an embodiment and a method of manufacturing a semiconductor device will be described with reference to the accompanying drawings. In the following description, components having the same or similar functions are denoted by the same reference numerals and signs. A repeated description of these components may be omitted. The drawings are schematic or conceptual, and the relationship between the thickness and the width of each portion, the size ratio between the components, and the like are not necessarily identical to those in reality. In this application, the term “connection” is not limited to a case of physical connection, and also includes a case of electrical connection. In this application, the terms “parallel,” “orthogonal,” and “same” also include “approximately parallel,” “approximately orthogonal,” and “approximately same,” respectively. In this application, the wording “extend in an A direction” means that, for example, dimensions in an A direction are larger than the smallest dimensions out of respective dimensions in an X direction, a Y direction, and a Z direction to be described later. The “A direction” referred to here is any direction.

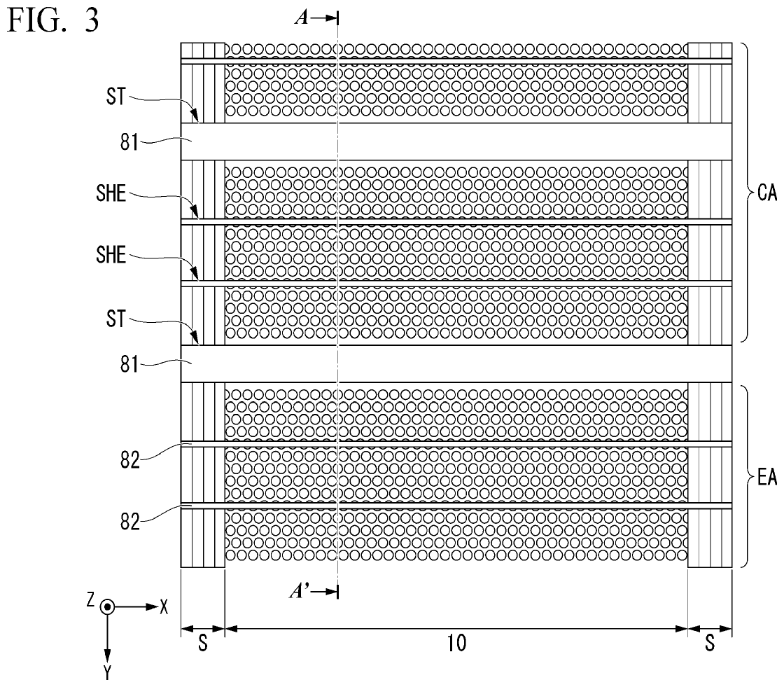

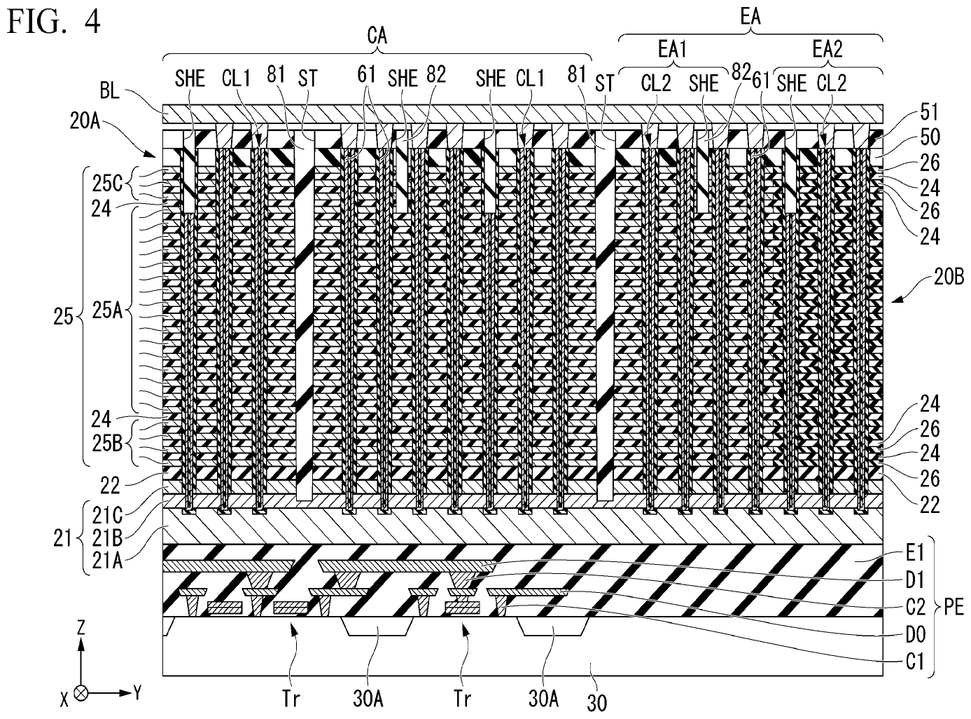

In addition, first, a +X direction, a −X direction, a +Y direction, a −Y direction, a +Z direction, and a −Z direction will be defined. The +X direction, the −X direction, the +Y direction, and the −Y direction are directions along the surface of a substrate 30 (see FIG. 4) to be described later. The +X direction is one of directions in which a separation portion 81 (see FIG. 3) to be described later extends. The −X direction is a direction opposite to the +X direction. In a case where the +X direction and the −X direction need not be distinguished from each other, these directions are simply referred to as the “X direction.” The +Y direction and the −Y direction are directions intersecting (for example, orthogonal to) the X direction. The +Y direction is one of directions in which a bit line BL (see FIG. 4) to be described later extends. The −Y direction is a direction opposite to the +Y direction. In a case where the +Y direction and the −Y direction need not be distinguished from each other, these directions are simply referred to as the “Y direction.” The +Z direction and the −Z direction are directions intersecting (for example, orthogonal to) the X direction and the Y direction, and are thickness directions of the substrate 30 (see FIG. 4). The +Z direction is a direction from the substrate 30 toward the bit line BL to be described later. The −Z direction is a direction opposite to the +Z direction. In a case where the +Z direction and the −Z direction need not be distinguished from each other, these directions are simply referred to as the “Z direction.” The Z direction corresponds to a vertical direction with respect to the surface of the substrate 30 used to form a semiconductor memory device 1. In the present specification, the “+Z direction” may be referred to as “upward,” and the “−Z direction” may be referred to as “downward.” However, these expressions are for convenience only, and do not specify the direction of gravity. The +Z direction is an example of a “first direction.” The +Y direction is an example of a “second direction.” The +X direction is an example of a “third direction.”

In each of plan views and cross-sectional views among the drawings referred to below, illustration of some components such as wirings, contacts, interlayer insulating films, and the like is appropriately omitted in order to make the drawings easier to understand.

### 1. Configuration of Semiconductor Memory Device

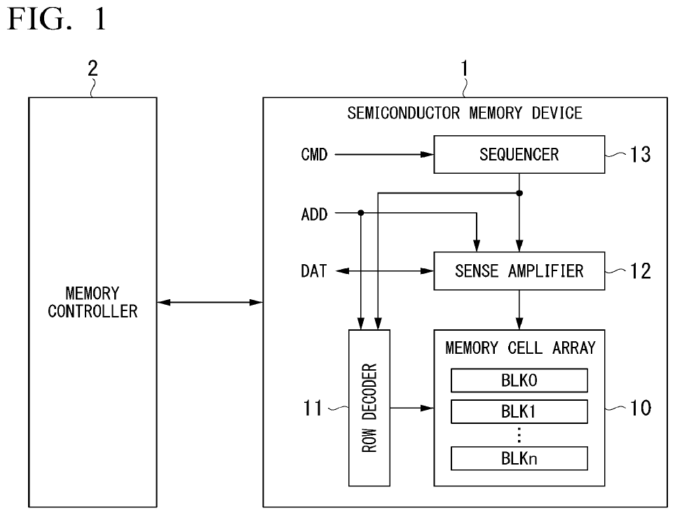

FIG. 1 is a block diagram illustrating the semiconductor memory device 1 and a memory controller 2. The semiconductor memory device 1 is a non-volatile semiconductor memory device and is, for example, a NAND-type flash memory. The semiconductor memory device 1 is controlled by the memory controller 2. Communication between the semiconductor memory device 1 and the memory controller 2 is compliant with, for example, the NAND interface standard. The semiconductor memory device 1 includes, for example, a memory cell array 10, a row decoder 11, a sense amplifier 12, and a sequencer 13.

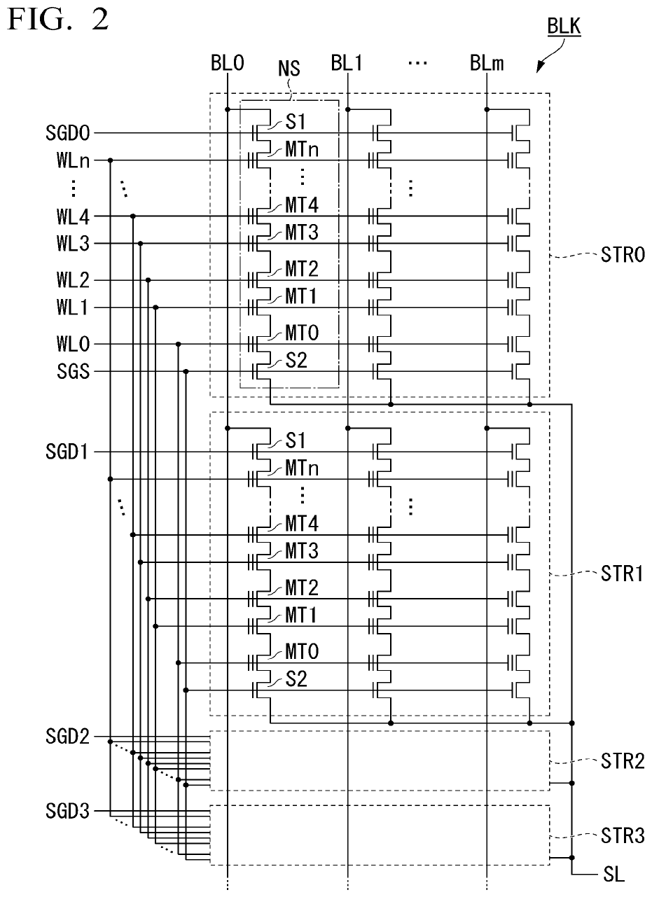

The memory cell array 10 includes a plurality of blocks BLKO to BLKn (n is an integer equal to or greater than 1). Each of the blocks BLK is a collection of non-volatile memory cell transistors MT (see FIG. 2). The memory cell array 10 is provided with a plurality of bit lines and a plurality of word lines. Each of the memory cell transistors MT is associated with one bit line and one word line.

The row decoder 11 selects one block BLK on the basis of address information ADD received from the external memory controller 2. The row decoder 11 applies a desired voltage to each of the plurality of word lines to control writing and read operations of data for the memory cell array 10.

The sense amplifier 12 applies a desired voltage to each bit line in accordance with write data DAT received from the memory controller 2 during a writing operation. On the other hand, during a read operation, the sense amplifier 12 determines the data stored in the memory cell transistor MT on the basis of the voltage of the bit line, and transmits the determined readout data DAT to the memory controller 2.

The sequencer 13 controls the operation of the entire semiconductor memory device 1 on the basis of a command CMD received from the memory controller 2.

The semiconductor memory device 1 described above is an example of a “semiconductor device.” In addition, the semiconductor memory device 1 and the memory controller 2 may be combined to constitute one memory system. Examples of memory systems include a memory card, a solid-state drive (SSD), and the like. Meanwhile, the “semiconductor device” is not limited to the semiconductor memory device 1, and may be, for example, a semiconductor device that does not have a memory function.

Next, the configuration of the memory cell array 10 will be described.

FIG. 2 is a diagram illustrating an equivalent circuit of a portion of the memory cell array 10. FIG. 2 shows the extraction of one block BLK included in the memory cell array 10. The block BLK includes a plurality of (for example, four) strings STR0 to STR3.

Each of the strings STR0 to STR3 is a collection of a plurality of NAND strings NS. One end of each NAND string NS is connected to any of bit lines BL0 to BLm (m is an integer equal to or greater than 1). The other end of each NAND string NS is connected to a source line SL. Each NAND string NS includes a plurality of memory cell transistors MT0 to MTn (n is an integer equal to or greater than 1), a first selection transistor S1, and a second selection transistor S2.

The plurality of memory cell transistors MT0 to MTn are electrically connected in series to each other. The memory cell transistor MT includes a control gate and a memory stacked film and stores data in a nonvolatile manner. The state of the memory stacked film changes in accordance with a relationship between the voltage applied to the control gate and the voltage applied to the bit line BL. For example, charge is accumulated in a charge accumulation film included in the memory stacked film. The control gate of the memory cell transistor MT is connected to any of corresponding word lines WL0 to WLn. The memory cell transistor MT is electrically connected to the row decoder 11 through the word line WL.

The first selection transistor S1 in each NAND string NS is connected between the plurality of memory cell transistors MT0 to MTn and any of the bit lines BL0 to BLm. The drain of the first selection transistor S1 is connected to any of the bit lines BL0 to BLm. The source of the first selection transistor S1 is connected to the memory cell transistor MTn. The control gate of the first selection transistor S1 in each NAND string NS is connected to any of selection gate lines SGD0 to SGD3.

The first selection transistor S1 is electrically connected to the row decoder 11 through the selection gate line SGD. The first selection transistor S1 connects the NAND string NS and the bit line BL in a case where a predetermined voltage is applied to the selection gate line SGD corresponding to the first selection transistor S1 among the selection gate lines SGD0 to SGD3.

The second selection transistor S2 in each NAND string NS is connected between the plurality of memory cell transistors MT0 to MTn and the source line SL. The drain of the second selection transistor S2 is connected to the memory cell transistor MT0. The source of the second selection transistor S2 is connected to the source line SL. The control gate of the second selection transistor S2 is connected to a selection gate line SGS. The second selection transistor S2 is electrically connected to the row decoder 11 through the selection gate line SGS. The second selection transistor S2 connects the NAND string NS and the source line SL in a case where a predetermined voltage is applied to the selection gate line SGS.

Meanwhile, the memory cell array 10 may have other circuit configurations than those described above. For example, the number of strings STR included in each block BLK, the number of memory cell transistors MT included in each NAND string NS, and the numbers of STD and STS may be changed. In addition, the NAND string NS may include one or more dummy transistors.

FIG. 3 is a plan view illustrating a portion of the semiconductor memory device 1 of the present embodiment. FIG. 4 is a cross-sectional view along plane A-A′ in FIG. 3.

As shown in FIGS. 3 and 4, the semiconductor memory device 1 of the present embodiment includes the memory cell array 10 and, for example, stepped portions S provided at both ends of the memory cell array 10 in the X direction. Each slit ST is provided from one stepped portion S through the memory cell array 10 to the other stepped portion S.

### <1.1 Memory Cell Array>

Next, an example of the structure of the memory cell array 10 of the semiconductor memory device 1 will be described.

The memory cell array 10 has a cell array region. The NAND strings NS are integrated in the cell array region.

The memory cell array 10 of the semiconductor memory device 1 has the substrate 30, a circuit layer PE, a cell array region CA, and an end region EA as shown in FIGS. 3 and 4. In the present embodiment, the cell array region CA is an example of a “first region,” and the end region EA is an example of a “second region.”

The cell array region CA has a first stack 20A in which a plurality of insulating films 24 and the plurality of conductive films 25 are alternately stacked in the Z direction, and a first pillar CL1 including a semiconductor layer 61. In the present embodiment, the insulating film 24 is an example of a “first insulating film,” and the conductive film 25 is an example of a “first conductive film.” The semiconductor layer 61 is an example of a “first semiconductor layer.”

As shown in FIG. 4, the end region EA has a second stack 20B in which the plurality of insulating films 24 and a plurality of stacked insulating film 26 are alternately stacked in the Z direction, and a second pillar CL2 including the semiconductor layer 61.

The substrate 30 is, for example, a silicon substrate. The surface region of the substrate 30 has a plurality of element isolation regions 30A. The element isolation regions 30A include, for example, a silicon oxide. The source region and drain region of the transistor Tr are located between the element isolation regions 30A adjacent to each other in the Y direction.

The circuit layer PE is located on the substrate 30. The circuit layer PE includes the row decoder 11, the sense amplifier 12, and the sequencer 13 of the semiconductor memory device 1. The circuit layer PE includes, for example, a plurality of transistors Tr, a plurality of wiring layers D0 and D1, and a plurality of vias C1 and C2. The plurality of transistors Tr, the plurality of wiring layers D0 and D1, and the plurality of vias C1 and C2 are located within an insulating layer E1. The wiring layers D0 and D1 and each transistor Tr are, for example, portions of the components of the row decoder or the sense amplifier. The wiring layers D0 and D1 and each transistor Tr are connected to, for example, each bit line BL or each word line WL. The insulating layer E1 includes, for example, a silicon oxide. The via C1 connects the source region or drain region of the transistor Tr and the wiring layer D0. The via C2 connects the gate region of the transistor Tr and the wiring layer D1. The vias C1 and C2 and the wiring layers D0 and D1 include, for example, tungsten.

### (Cell Array Region CA)

The cell array region CA has the first stack 20A and a plurality of first pillars CL1 including the semiconductor layer 61.

The first stack 20A has a conductive film 21, an insulating film 22, the plurality of conductive films 25, and the plurality of insulating films 24 in the Z direction. The conductive film 21 and the plurality of conductive films 25 spread in the X direction and the Y direction. The insulating film 22 and the plurality of insulating films 24 spread in the X direction and the Y direction. The plurality of insulating films 24 and the plurality of conductive films 25 are alternately stacked one by one in the Z direction.

The insulating film 22 is located between the conductive film 21 and the conductive film 25. The insulating film 24 is located between the conductive films 25 adjacent to each other in the Z direction. The insulating film 24 allows insulation between two conductive films 25 adjacent to each other in the Z direction. The number of layers of the insulating film 24 is determined by the number of layers of the conductive film 25. The film thickness of the insulating film 24 is, for example, equal to or more than 10 nm and equal to or less than 20 nm. The insulating film 22 and the plurality of insulating films 24 contain, for example, a silicon oxide.

The plurality of conductive films 25 spread in the X direction and the Y direction. That is, the conductive films 25 each are formed in a plate shape spread in the X direction and the Y direction. The conductive film 25 is, for example, tungsten or polysilicon doped with impurities. The number of layers of the conductive film 25 is arbitrary.

The plurality of conductive films 25 includes a plurality of first conductive films 25A stacked in the Z direction, a second conductive film 25B located between the substrate 30 and the plurality of first conductive films 25A in the Z direction, and a third conductive film 25C located opposite to the substrate 30 with respect to the plurality of first conductive films 25A in the Z direction. The plurality of conductive films 25 are functionally divided into, for example, three. The plurality of conductive films 25 function as any of the source-side selection gate line SGS, the word line WL, and the drain-side selection gate line SGD. In example shown in FIG. 4, the second conductive film 25B corresponds to the source-side selection gate line SGS, the first conductive film 25A corresponds to the word line WL, and the third conductive film 25C corresponds to the drain-side selection gate line SGD.

Among the plurality of conductive films 25, for example, four layers of the second conductive film 25B, starting from the bottom of the first stack 20A, function as the source-side selection gate lines SGS as described above. The number of layers of the second conductive film 25B functioning as the source-side selection gate line SGS is not limited, and the second conductive film 25B may be a single layer or multiple layers. That is, the source-side selection gate line SGS may be constituted by one layer of the second conductive film 25B, or may be constituted by multiple layers of the second conductive film 25B. In addition, in a case where the source-side selection gate line SGS is constituted by multiple layers, each of the second conductive films 25B may be constituted by conductors different from each other.

In the present embodiment, among the plurality of conductive films 25, three layers of the third conductive film 25C, starting from the top of the first stack 20A, function as the drain-side selection gate lines SGD as described above. The number of layers of the third conductive film 25C functioning as the drain-side selection gate line SGD is not limited. The third conductive film 25C may be a single layer or multiple layers. That is, the drain-side selection gate line SGD may be constituted by one layer of the third conductive film 25C, or may be constituted by multiple layers of the third conductive film 25C. In addition, in a case where the drain-side selection gate line SGD is constituted by multiple layers, each of the third conductive films 25C may be constituted by conductors different from each other.

Among the plurality of conductive films 25, the first conductive film 25A other than the second conductive film 25B and the third conductive film 25C functions, for example, as the word line WL. The number of layers of the first conductive film 25A functioning as the word line WL is not limited. The first conductive film 25A, the second conductive film 25B, and the third conductive film 25C surround, for example, the outer circumference of the first pillar CL1.

The conductive film 21 is disposed above the circuit layer PE. The conductive film 21 includes semiconductor layers 21A, 21B, and 21C. The semiconductor layer 21A is located on the circuit layer PE. The semiconductor layer 21A is, for example, an n-type semiconductor. The semiconductor layer 21A is, for example, polysilicon doped with impurities. The semiconductor layer 21B is located on the semiconductor layer 21A. The semiconductor layer 21B is in contact with the semiconductor layer 61 of the first pillar CL1. The semiconductor layer 21B is, for example, an epitaxial film doped with impurities. The semiconductor layer 21B contains, for example, phosphorus. The semiconductor layer 21C is located on the semiconductor layer 21B. The semiconductor layer 21C is, for example, an n-type or non-doped semiconductor.

Cover insulating layers 50 and 51 are located above the conductive film 25C which is the uppermost layer of the first stack 20A. The cover insulating layers 50 and 51 allow insulation between the first stack 20A and the bit line BL. The cover insulating layers 50 and 51 contain, for example, a silicon oxide.

The bit line BL is formed above cover insulating layer 51, for example, in a line shape extending in the Y direction, and is electrically connected to the first pillar CL1. A plurality of bit lines BL are arrayed in the X direction in a region which is not shown.

The plurality of first pillars CL1 are provided in the first stack 20A. Each of the plurality of first pillars CL1 extends in the Z direction. Each of the plurality of first pillars CL1 extends, for example, up to the middle of the semiconductor layer 21A in the Z direction. The lower portion of the first pillar CL1 is in contact with the semiconductor layer 21A. The upper portion of the first pillar CL1 is in contact with the cover insulating layer 50. The details of the specific structure of the first pillar CL1 will be described later.

### (End Region EA)

The end region EA is a region located at the end of the memory cell array 10 which is adjacent to the cell array region CA in the Y direction. The end region EA has the second stack 20B and a plurality of second pillars CL2 including the semiconductor layer 61. As shown in FIG. 4, the end region EA includes, for example, a replaced region EA1 and a non-replaced region EA2. The structure of the replaced region EA1 may be the same as the structure of the first stack 20A in the cell array region CA. The structure of the non-replaced region EA2 will be detailed later.

The second stack 20B has the conductive film 21, the insulating film 22, the plurality of insulating films 24, a plurality of insulating films 26a, and a plurality of insulating films 26b in the Z direction. The insulating film 24, the insulating film 26a, and the insulating film 26b are repeatedly stacked in this order in the Z direction. The plurality of insulating films 26a and the plurality of insulating films 26b spread in the X direction and the Y direction. The configurations of the conductive film 21 and the insulating film 22 in the end region EA are the same as those in the cell array region CA.

The plurality of insulating films 24 spread in the X direction and the Y direction. The plurality of insulating films 24 contain, for example, a silicon oxide. The insulating film 24 is located between the insulating film 26a and the insulating film 26b adjacent to each other in the Z direction. The number of layers of the insulating film 24 is determined by the number of layers of the insulating film 26a and the insulating film 26b. The film thickness of the insulating film 24 is, for example, equal to or less than 20 nm.

The plurality of insulating films 26a spread in the X direction and the Y direction. That is, each of the insulating films 26a is formed in a plate shape spread in the X direction and the Y direction. The insulating film 26a contains, for example, a silicon nitride. The number of layers of the insulating film 26a is arbitrary. The film thickness of the insulating film 26a is, for example, equal to or more than 10 nm and equal to or less than 30 nm. In addition, the insulating film 26a is in contact with the insulating film 24 on the circuit layer PE side in the Z direction.

The plurality of insulating films 26b spread in the X direction and the Y direction. That is, each of the insulating films 26b is formed in a plate shape spread in the X direction and the Y direction. The insulating film 26b is provided on the insulating film 26a and located below the insulating film 24. The insulating film 26b contains, for example, a silicon nitride and further contains oxygen or hydrogen. The number of layers of the insulating film 26b is determined by the number of layers of the insulating film 26a, and may be the same as, for example, the number of layers of the insulating film 26a.

During the formation of a memory hole MH using dry etching, the plurality of insulating films 26b have a function of preventing carbon fluoride (CF) from adhering to the sidewall in the memory hole MR. The insulating film 26b is in contact with the insulating film 24.

The average hydrogen concentration per unit volume of the insulating film 26b is more than 15 atom %. As will be described later in detail, causing hydrogen to be contained in the insulating film 26b containing a silicon nitride (SiN) makes it possible to prevent carbon fluoride (CF) from adhering to the sidewall in the memory hole MH during the formation of the memory hole MH. As a result, it is possible to reduce the amount of SiN chipping (that is, chipping size) at the interface between the insulating film 26a and the insulating film 24 which has occurred in a memory cell array of a comparative example. When the amount of SiN chipping increases, the variation in threshold voltage increases, which may lead to instability of electrical characteristics. However, by setting the average hydrogen concentration of the insulating film 26b to be equal to or more than 15 atom %, it is possible to reduce the amount of SiN chipping and to stabilize the electrical characteristics. In order to enjoy this effect more, it is preferable to set the average hydrogen concentration of the insulating film 26b to be equal to or more than 19 atom %. Meanwhile, in order to reduce the dimensions of SiN chipping to 3 nm or less and further enhance the stabilization of the electrical characteristics, it is preferable to set the average hydrogen concentration of the insulating film 26b to be equal to or more than 19.8 atom %.

Meanwhile, in the present embodiment, hydrogen may be contained in the insulating film 26a. However, in a case where hydrogen is contained in the insulating film 26a, it is preferable that the hydrogen concentration of the insulating film 26b be higher than the hydrogen concentration of the insulating film 26a in the lamination direction. In addition, in the present embodiment, with a microscope such as a scanning electron microscope (SEM), it may be difficult to clearly distinguish the interface between the insulating film 26a and the insulating film 26b. In such a case, it is possible to distinguish from the difference in hydrogen concentration measured by Rutherford backscattering spectrometry/hydrogen forward scattering spectrometry (RBS/HFS).

In RBS/HFS, first, an insulating film to be measured is irradiated with accelerated He ions, and back-scattered He atoms and forward-scattered H atoms are detected. Thereafter, the composition of the insulating film can be obtained by analyzing an obtained energy spectrum.

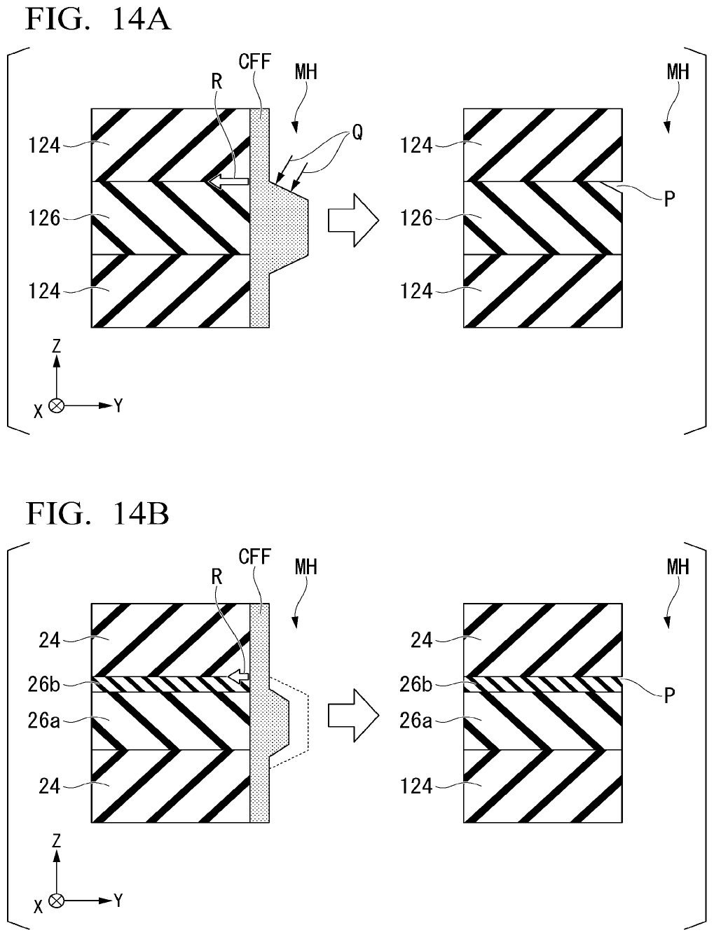

Here, “SiN chipping” will be described with reference to FIGS. 14A and 14B. FIGS. 14A and 14B are schematic diagrams illustrating the generation mechanism of SiN chipping. FIG. 14A is a cross-sectional view illustrating the vicinity of a memory hole during formation of the memory hole of the comparative example. FIG. 14B is a cross-sectional view illustrating the vicinity of a memory hole during formation of the memory hole of the present embodiment.

“SiN chipping” is “chipping” that occurs at the interface between a conductive film and an insulating film due to carbon fluoride (CF) derived from a gas (CxFy-based gas) used during formation of a memory hole, that is, during dry etching, being attached to and deposited on the sidewall in the memory hole. Specifically, as shown in FIG. 14A, the memory hole MH is formed in a stack in which insulating films 124 containing a silicon oxide and insulating films 126 containing a silicon nitride are alternately stacked, and the memory hole MH is formed through dry etching using a CxFy-based gas. In this case, as shown in FIG. 14A, carbon fluoride (CF) derived from a CxFy-based gas adheres to the sidewall in the memory hole MEI and is deposited as a carbon fluoride film (CF film) CFF. However, since the carbon fluoride film CFF has a tendency to adhere more readily to the insulating film 126 containing a silicon nitride out of the insulating film 124 and the insulating film 126 which are exposed on the sidewall in the memory hole MH, the carbon fluoride film CFF on the sidewall of the insulating film 126 becomes larger. That is, a difference occurs in the film thickness of the carbon fluoride film CFF deposited on the sidewall in the memory hole MH. When the carbon fluoride film CFF on the sidewall of the insulating film 126 becomes larger, an etching gas collides with the upper surface of the carbon fluoride film CFF in the Z direction (see an arrow Q in the drawing), and along with this, fluorine constituting the CF film thermally diffuses along the interface between the insulating film 124 and the insulating film 126 (see an arrow R in the drawing). As a result, SiN chipping P occurs on the upper surface (interface) of the insulating film 126. When the constituent elements of each pillar (such as, for example, a charge accumulation film and a cover insulating film) are formed in the memory hole MH in a state where such SiN chipping P occurs, the constituent elements may enter the SiN chipping P, which leads to a deterioration in the electrical characteristics such as occurrence of variations in write voltage.

Consequently, in the present embodiment, as shown in FIG. 14B, the carbon fluoride film CFF can be prevented from adhering to the sidewall in the memory hole MH by providing the insulating film 26b on the insulating film 26a, and thus it is possible to reduce the thickness of the CF film deposited on the lateral sides of the insulating film 26a and the insulating film 26b. Thereby, the amount of thermal diffusion of fluorine is reduced, and as a result, it is possible to reduce the size of the SiN chipping P. This is presumably because hydrogen contained in the insulating film 26b acts effectively. Specifically, as compared with nitrogen elements, hydrogen elements are more likely to bond with carbon elements and have the effect of promoting detachment of carbon elements from the sidewall in the memory hole MH. Therefore, it is considered that the amount of deposition of the carbon fluoride film CFF can be reduced.

The element contained in the insulating film 26b may be oxygen instead of hydrogen. Even in a case where oxygen is contained in the insulating film 26b, the effect of containing hydrogen as described above can be achieved. In order to achieve the above effect, the average oxygen concentration per unit volume in the insulating film 26b should be more than 5 atom %. Preferably, it is equal to or more than 10 atom %. Meanwhile, in order to reduce the dimensions of SiN chipping to 3 nm or less and further enhance the stabilization of the electrical characteristics, the average oxygen concentration of the insulating film 26b is more preferably equal to or more than 17 atom %, and more preferably equal to or more than 33.9 atom %.

Meanwhile, both hydrogen and oxygen may be contained in the insulating film 26b. Even in that case, the above effect can be enjoyed. In a case where both hydrogen and oxygen are contained in the insulating film 26b, the total amount thereof is preferably equal to or more than 19 atom %. The oxygen concentrations in the insulating film 26a and the insulating film 26b can be measured by the RBS/HFS described above, similarly to the method for measuring the hydrogen concentrations.

The film thickness of each of the plurality of insulating films 26b is preferably equal to or more than 0.5 nm. In a case where the film thickness of the insulating film 26b is equal to or more than 0.5 nm, it is possible to stably prevent carbon fluoride from adhering to the sidewall in the memory hole MH during the formation of the memory hole MH. As a result, it is possible to reduce the amount of SiN chipping and to stabilize the electrical characteristics. The film thickness of each of the plurality of insulating films 26b is more preferably equal to or more than 1 nm.

The cover insulating layer 50 and the bit line BL in the end region EA have the same configurations as the cover insulating layer 50 and the bit line BL in the cell array region CA.

The plurality of second pillars CL2 are provided in the second stack 20B. Each of the plurality of second pillars CL2 extends in the Z direction. Each of the plurality of second pillars CL2 extends, for example, up to the middle of the semiconductor layer 21A in the Z direction. The lower portion of the second pillar CL2 may be located, for example, inside the semiconductor layer 21A. The upper portion of the second pillar CL2 is in contact with the cover insulating layer 50. The specific structure of the second pillar CL2 is the same as that of the first pillar CL1, but the second pillar CL2 in the end region EA is a so-called dummy pillar that does not contribute to a memory operation. Therefore, the bit line BL is provided on the second pillar CL2, but is not electrically connected to the second pillar CL2.

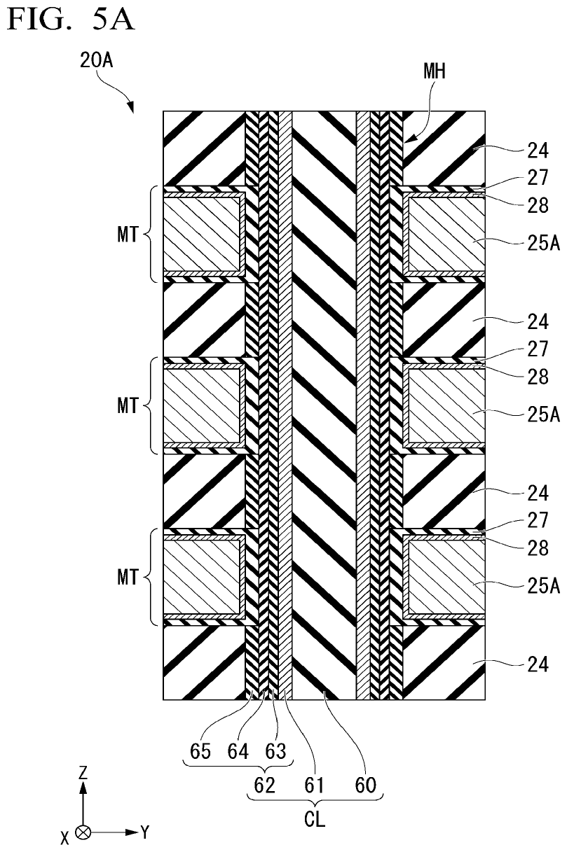

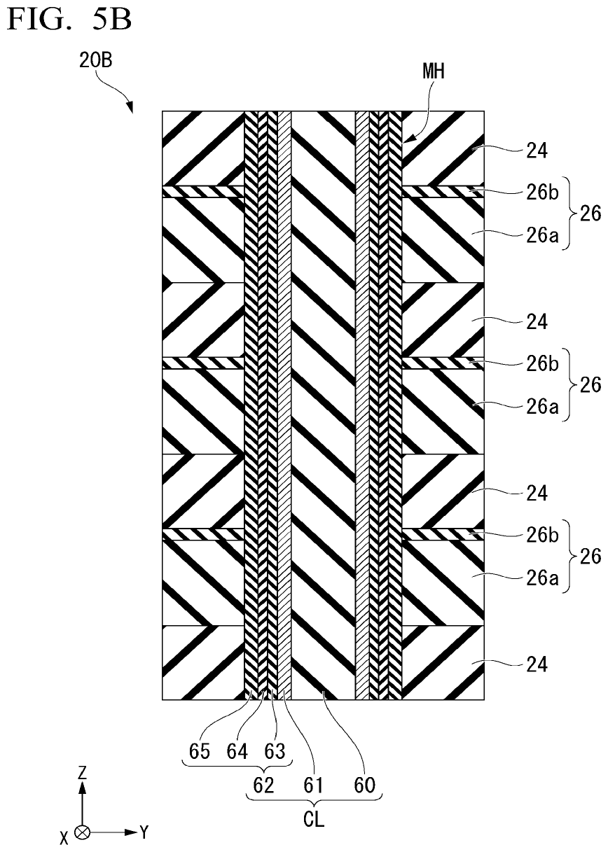

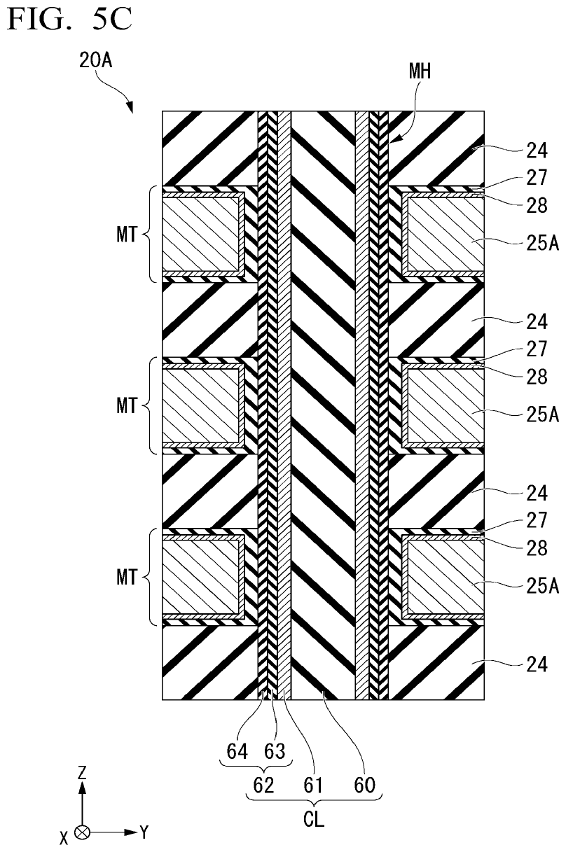

FIG. 5A is an enlarged cross-sectional view of the vicinity of the first pillar CL1 in the cell array region CA. FIG. 5B is an enlarged cross-sectional view of the vicinity of the second pillar CL2 in the non-replaced region EA2 in the end region EA. FIGS. 5A and 5B are cross sections obtained by cutting the first pillar CL1 and the second pillar CL2 along YZ plane.

As shown in FIG. 5B, the stacked insulating film 26 in the non-replaced region EA2 in the end region EA has the insulating film 26a and the insulating film 26b. That is, the second stack 20B located in the non-replaced region EA2 is configured by alternately laminating the plurality of insulating films 24, the plurality of insulating films 26a, and the plurality of insulating films 26b in the Z direction in the order of the insulating film 24, the insulating film 26a, and the insulating film 26b. In the present embodiment, the insulating film 26a is an example of a “second insulating film.” The insulating film 26b is an example of a “third insulating film.”

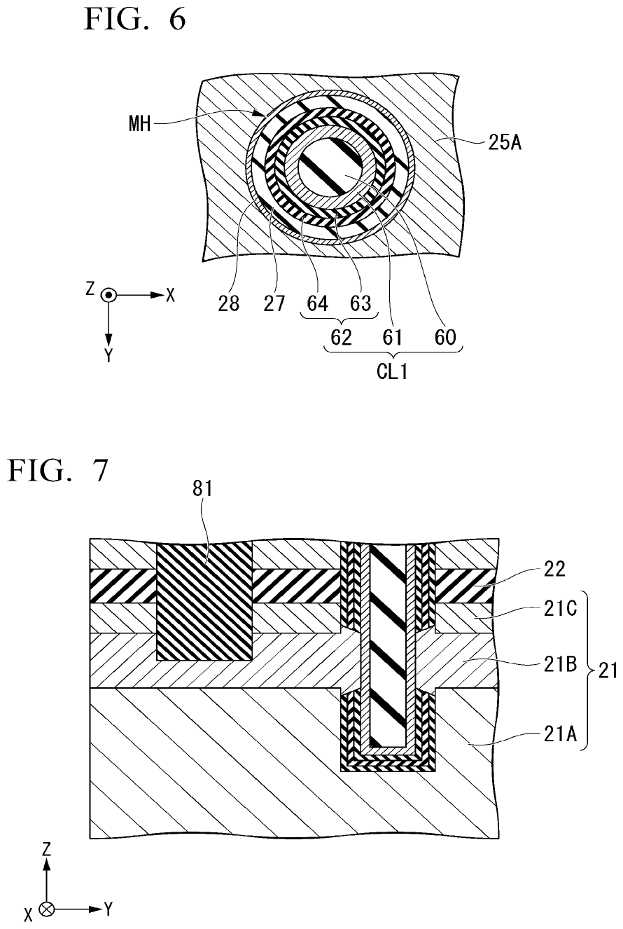

FIG. 6 is a cross-sectional view of the vicinity of the first pillar CL1 cut along the conductive film 25. FIG. 6 is a cross section obtained by cutting the first pillar CL1 along the XY plane. Each of the plurality of first pillars CL1 and the plurality of second pillars CL2 is formed in the memory hole MH and has an insulating core 60, the semiconductor layer 61, and the memory stacked film 62 in order from the inside.

The insulating core 60 extends in the Z direction and is columnar in shape. The insulating core 60 contains, for example, a silicon oxide. The insulating core 60 is provided in the central portion including the central axis of the memory hole MH when viewed in the Z direction.

The semiconductor layer 61 extends in the Z direction. The semiconductor layer 61 is formed, for example, in an annular shape and covers the outside surface (outer circumferential surface) of the insulating core 60. The semiconductor layer 61 contains, for example, silicon. Silicon is, for example, polysilicon obtained by crystallizing amorphous silicon. The semiconductor layer 61 functions as a channel for each of the first selection transistor 51, a plurality of memory cell transistors MT, and the second selection transistor S2. The term “channel” referred to here is a flow path for carriers between the source side and the drain side.

The memory stacked film 62 extends in the Z direction. The memory stacked film 62 covers the outside surface (outer circumferential surface) of the semiconductor layer 61. The memory stacked film 62 is located between the inside surface(inner circumferential surface) of the memory hole MH and the outside surface (outer circumferential surface) of the semiconductor layer 61. The memory stacked film 62 includes, for example, a tunnel insulating film 63, a charge accumulation film 64, and a cover insulating film 65. These films are provided in the order of the tunnel insulating film 63, the charge accumulation film 64, and the cover insulating film 65 from the semiconductor layer 61 side.

The tunnel insulating film 63 covers the outside surface of the semiconductor layer 61. That is, the tunnel insulating film 63 is located between the charge accumulation film 64 and the semiconductor layer 61. The tunnel insulating film 63 contains, for example, a silicon oxide or a silicon oxide and a silicon nitride. The tunnel insulating film 63 is a potential barrier between the semiconductor layer 61 and the charge accumulation film 64.

The charge accumulation film 64 covers the outside surface of the tunnel insulating film 63. That is, the charge accumulation film 64 is located between the conductive film 25 and the tunnel insulating film 63. The charge accumulation film 64 contains, for example, a silicon nitride. A portion where the charge accumulation film 64 and each of the plurality of conductive films 25 intersect each other functions as the memory cell transistor MT. The memory cell transistor MT holds data depending on the presence or absence of charge within the portion (charge accumulation portion) where the charge accumulation film 64 and each of the plurality of conductive films 25 intersect each other or the amount of charge accumulated. The charge accumulation film 64 is located between each of the conductive films 25 and the semiconductor layer 61 and is surrounded by an insulating material.

In the case of the cell array region CA, the cover insulating film 65 is located between, for example, each of insulating layers 24 and the charge accumulation film 64 as shown in FIG. 5A. The cover insulating film 65 contains, for example, a silicon oxide. The cover insulating film 65 protects the charge accumulation film 64 from etching during processing.

FIG. 5C is an enlarged cross-sectional view of a modification example of the first pillar CL1 and its vicinity in the cell array region CA. As shown in FIG. 5C, the cover insulating film 65 may be omitted in the first pillar CL1, or may be partially left between the conductive layer 25 and the charge accumulation film 64 and used as a block insulating film. Meanwhile, in the case of a portion of the end region EA, the insulating film 26a and the insulating film 26b are not influenced by a replacement process (that is, remain), and thus the cover insulating film 65 covers the outside surface of the charge accumulation film 64 without being divided in the Z direction as shown in FIG. 5A. That is, the outside surface of the cover insulating film 65 in the non-replaced region EA2 in the end region EA is in contact with the insulating film 24, the insulating film 26a, and the insulating film 26b.

In addition, in the cell array region CA, a block insulating film 27 and a barrier film 28 may be provided between each of the conductive films 25 and the insulating film 24 and between each of the conductive films 25 and the memory stacked film 62. The block insulating film 27 suppresses back tunneling. Back tunneling is a phenomenon in which charges return from the conductive film 25 to the memory stacked film 62. The barrier film 28 improves adhesion between the conductive film 25 and the block insulating film 27. The block insulating film 27 is, for example, a silicon oxide film or a metal oxide film. An example of a metal oxide is an aluminum oxide. For example, in a case where the conductive film 25 is made of tungsten, the barrier film 28 is a stacked structure film of a titanium nitride and titanium as an example.

FIG. 7 is an enlarged cross-sectional view of the vicinity of the conductive film 21. FIG. 7 is a cross section obtained by cutting the conductive film 21 and the first pillar CL1 along a plane parallel to the Y direction and the Z direction (YZ plane). The conductive film 21 includes, for example, the semiconductor layer 21A, the semiconductor layer 21B, and the semiconductor layer 21C as described above. The conductive layer 21 is connected to each of the plurality of first pillars CL1. The conductive film 21 is formed, for example, in a plate shape spread in the X direction and the Y direction, and functions as the source line SL. Meanwhile, the conductive film 21 in the end region EA may also have the same structure as in FIG. 7.

Here, as shown in FIG. 3, the semiconductor memory device 1 of the present embodiment has a plurality of slits ST and slits SHE in a plan view from the Z direction. The plurality of slits ST are grooves that divide the first stack 20A in the Y direction and divide the first stack 20A and the second stack 20B in the Y direction. That is, the cell array region CA and the end region EA are divided by the slit ST in the Y direction. The plurality of slits ST all extend in the X direction. Meanwhile, the end region EA includes, for example, a replaced region EA1 and a non-replaced region EA2 as shown in FIG. 4. The structure of the replaced region EA1 may be the same as the structure of the first stack 20A in the cell array region CA as shown in FIG. 5A. On the other hand, the structure of the non-replaced region EA2 in the end region EA is a stacked structure as shown in FIG. 5B.

Each of the plurality of slits ST is a deep slit, penetrates through the first stack 20A and the second stack 20B, and extends from the upper surface of the cover insulating layer 50 to the conductive film 21. A first separation portion 81 is disposed in the slit ST. The first separation portion 81 is, for example, an insulator containing a silicon oxide. The first stack 20A located between the slits ST adjacent to each other in the Y direction is referred to as a block (see “BLKn” in FIG. 1) and constitutes, for example, the minimum unit of data erasure. Meanwhile, a conductor (for example, tungsten, Poly-Si, or the like) may be disposed in the first separation portion 81. That is, the first separation portion 81 may have a stacked structure in which a conductor is disposed inside an insulator. The first separation portion 81 is an example of a “first insulator.”

The plurality of slits SHE are shallow slits, and are provided from the upper surface of the cover insulating layer 50 up to the middle of the first stack 20A and the middle of the second stack 20B. A second separation portion 82 is disposed in the slit SHE. A region separated by two slits SHE adjacent to each other in the Y direction is a so-called string (STR). The second separation portion 82 is, for example, an insulator containing a silicon oxide.

Meanwhile, the planar layout of the memory cell array of the semiconductor memory device 1 is not limited to the layout shown in FIG. 3, and may be any other layout. For example, the number of first pillars CL1 in one string adjacent to each other and the arrangement thereof can be appropriately changed.

### <1.2 Operation>

As described above, the end region EA and the cell array region CA are divided by the slit ST. The end region EA is located at the end of the memory cell array 10 in the Y direction as described above. The end is a region where an etchant introduced from the slit ST during replacement does not reach (is not influenced) as will be described in a manufacturing method to be described later. That is, a region at a certain distance in the Y direction from the slit ST in the stack located in the end region EA remains without the insulating film 26b which is a sacrificial film being removed. However, since the end region EA is a region that does not function as a memory, there is no adverse influence due to the insulating film 26b remaining (that is, not being replaced with the conductive film 25), and it does not pose any problems in terms of the functionality of the semiconductor memory device 1.

In the present embodiment, in the end region EA, the insulating film 26b is provided between the insulating film 24 and the insulating film 26a. This makes it possible to prevent the CF film from adhering to the sidewall in the memory hole MH during replacement and to, as a result, prevent SiN chipping during the formation of the memory hole MH from occurring.

When SiN chipping occurs, as described above, some of constituent elements of each pillar (for example, the charge accumulation film 64 and the cover insulating film 65) provided in the memory hole MH may enter the SiN chipping, which leads to a deterioration in the electrical characteristics such as occurrence of variations in write voltage.

In the present embodiment, the amount of SiN chipping (that is, size) can be reduced by providing the insulating film 26b including a silicon nitride containing hydrogen and/or oxygen on the insulating film 24a (that is, in the +Z direction) and then forming the memory hole MH using dry etching (see FIG. 14B). Meanwhile, in the case of the semiconductor memory device 1 of the present embodiment, the insulating film 26a is present in the end region EA, but the insulating film 26a is also present in the formation region of the cell array region CA during the manufacturing process. However, since the insulating film 26a which is present in the formation region of the cell array region CA is replaced with the conductive film 25 through the replacement process, the insulating film 26a does not remain in the cell array region CA of the semiconductor memory device 1 which is a final form. However, since the insulating film 26a is present in each formation region of the end region EA and the cell array region CA during the manufacturing process, SiN chipping in the cell array region CA can also made smaller than in the comparative example. The wording “dimensions of SiN chipping” referred to here indicates the maximum length of chipping in the Y direction at the interface between the insulating film 26b and the insulating film 24.

Meanwhile, as described above, the insulating film 26a and the insulating film 26b are replaced with the conductive film 25 in most of the memory cell array 10 (excluding the end region EA) through replacement. Therefore, at least in the cell array region CA, the insulating film 26a and the insulating film 26b are removed and do not remain. However, since a portion of the end region EA is not influenced by the replacement process, whether the memory hole is formed using the insulating film 26b can be determined from the configuration of the stack 20B in the end region EA, that is, whether the insulating film 26b remains in the end region EA.

As described above, in the semiconductor memory device 1 of the present embodiment, the insulating film 26b is provided between the insulating film 24 and the insulating film 26a in the end region EA as a layer for preventing the CF film from adhering to the sidewall in the memory hole MH during replacement, and thus it is possible to reduce the amount of SiN chipping. As a result, it is possible to improve the electrical characteristics of the semiconductor memory device 1.

### <2. Method of Manufacturing Semiconductor Device>

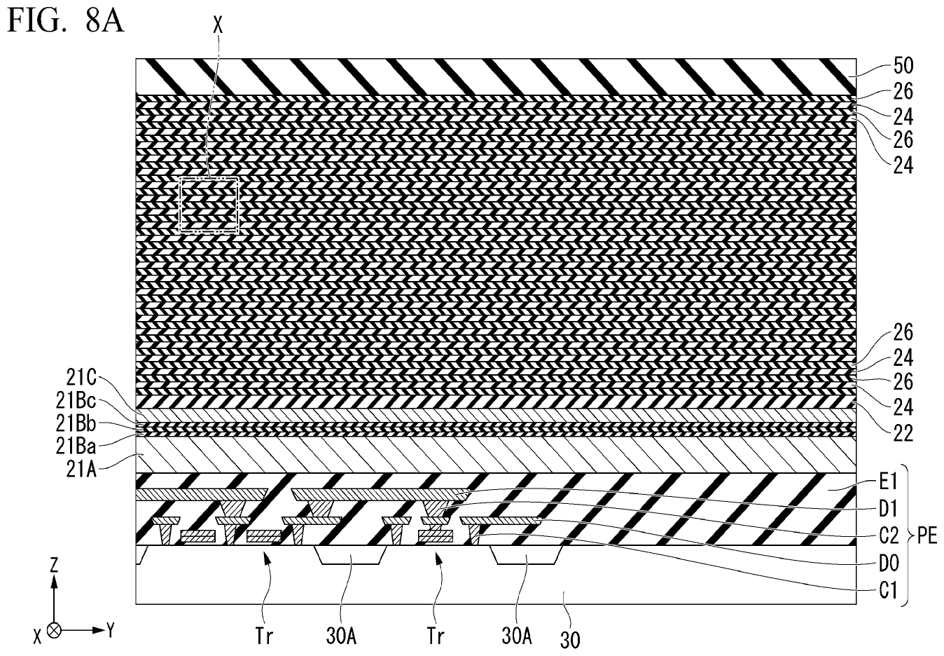

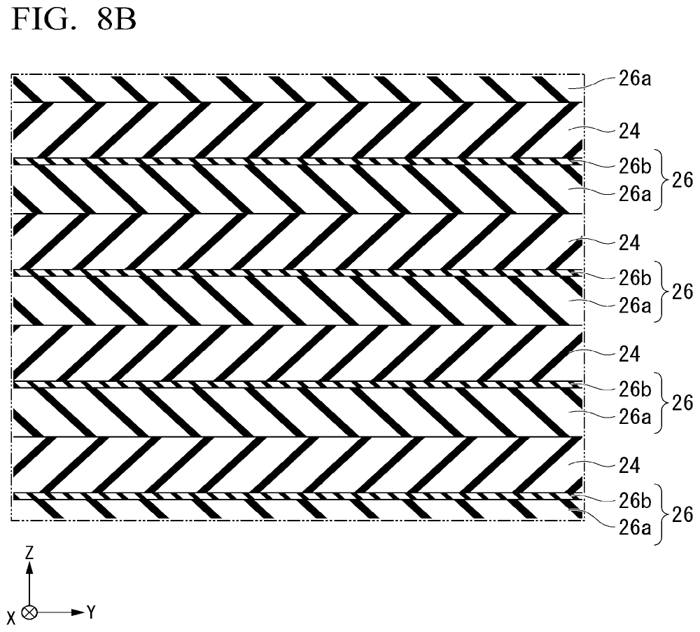

Next, a method of manufacturing a semiconductor device of the present embodiment will be described. Hereinafter, the semiconductor memory device 1 of the present embodiment is taken as an example of a semiconductor device, and a method of manufacturing the same will be described. FIGS. 8A to 11 are cross-sectional views illustrating a method of manufacturing the semiconductor memory device 1 of the present embodiment. Meanwhile, FIG. 8B is an enlarged view of a region X in FIG. 8A.

First, as shown in FIG. 8A, the element isolation regions 30A are formed in the substrate 30, and the transistors Tr are formed in the circuit layer PE. The transistor Tr can be formed using a known method. In addition, in the circuit layer PE, a plurality of wiring layers D0 and D1 and a plurality of vias C1 and C2 electrically connected to the transistors Tr are formed in the insulating layer E1. The plurality of wiring layers D0 and D1 and the plurality of vias C1 and C2 can be formed using a known method.

Next, the semiconductor layer 21A, an intermediate film 21Ba, a first sacrificial film 21Bb, an intermediate film 21Bc, the semiconductor layer 21C, and the insulating film 22 are stacked in this order on the circuit layer PE. The intermediate film 21Ba and the intermediate film 21Bc contain, for example, a silicon oxide. The first sacrificial film 21Bb is, for example, a silicon nitride. The semiconductor layer 21A, the semiconductor layer 21C, and the insulating film 22 are the same as those described above.

Next, as shown in FIG. 8A, the insulating film 24 and the stacked insulating film 26 are alternately stacked on the insulating film 22 (lamination step). Specifically, as shown in FIG. 8B, the stacked insulating film 26 is formed by alternately laminating the insulating film 26a and the insulating film 26b on the insulating film 24 in the Z direction. The insulating layer 24 is as described above and contains, for example, a silicon oxide. The insulating film 26a contains, for example, a silicon nitride. The insulating film 26b contains, for example, a silicon nitride and further contains hydrogen or/and oxygen.

The average hydrogen concentration of the insulating film 26b may be more than 20 atom %. Hydrogen contained in the insulating film 26b has an effect of preventing the CF film from adhering to the sidewall in the memory hole MH during the formation of the memory hole MH. In order to exhibit the effect, the average hydrogen concentration of the insulating film 26b should be more than 20 atom %. It is preferably equal to or more than 24.9 atom %, and more preferably equal to or more than 31.8 atom %. Meanwhile, the hydrogen concentration of the insulating film 26b is reduced through annealing treatment which is performed after the lamination step. Therefore, the average hydrogen concentration in the insulating film 26b after annealing may decrease by, for example, about 5 atom % from the average hydrogen concentration during the lamination step. That is, the average hydrogen concentration in the manufacturing method of the present embodiment is the average hydrogen concentration before annealing treatment.

As an element contained in the insulating film 26b, oxygen may be used instead of hydrogen. Even in a case where oxygen is contained in the insulating film 26b, it is possible to achieve the effect of preventing the CF from adhering. In a case where oxygen is contained in the insulating film 26b, the average oxygen concentration should be more than 5 atom %. It is preferably equal to or more than 10 atom %. Meanwhile, in order to reduce the dimensions of SiN chipping to be equal to or less than 3 nm and further enhance the stabilization of the electrical characteristics, the average oxygen concentration of the insulating film 26b is more preferably equal to or more than 17 atom %, and more preferably equal to or more than 33.9 atom %. Meanwhile, both hydrogen and oxygen may be contained in the insulating film 26b.

Here, a method of forming the insulating film 26b will be described.

Like the insulating film containing a silicon nitride (hereinafter also referred to as a SiN film) 26a, the insulating film 26b is a film with a silicon nitride as a main component, and has a composition in which hydrogen or/and oxygen is added to the silicon nitride. That is, the SiN film 26a and the insulating film 26b are common in that both contain SiN as a main component. Thus, the SiN film 26a and the insulating film 26b may be formed individually, or can also be formed continuously by plasma chemical vapor deposition (CVD). For example, the insulating film 26b can be formed by appropriately changing film-forming conditions during the formation of the SiN film 26a. Specifically, in a case where hydrogen is contained, for example, the hydrogen concentration in the insulating film 26b can be adjusted within the above range by changing one or more of the following conditions during the formation of the insulating film 26a; pressure, power of a high-frequency power source (HF power (W)), the flow rate of SiH₄ gas, and the flow rate of NH gas. For example, in a case where the hydrogen concentration in SiN is desired to be increased, the flow rate of SiH₄ gas need only be increased. In addition, in a case where oxygen is contained in the insulating film 26b, the oxygen concentration in the insulating film 26b can be adjusted within the above range by changing the flow rate of N₂O gas. In a case where both hydrogen and oxygen are contained in the insulating film 26b, the concentration of each element can be adjusted by appropriately combining the above conditions.

Next, the cover insulating layer 50 is formed on the insulating film 26b located at the uppermost portion to form the stack 20.

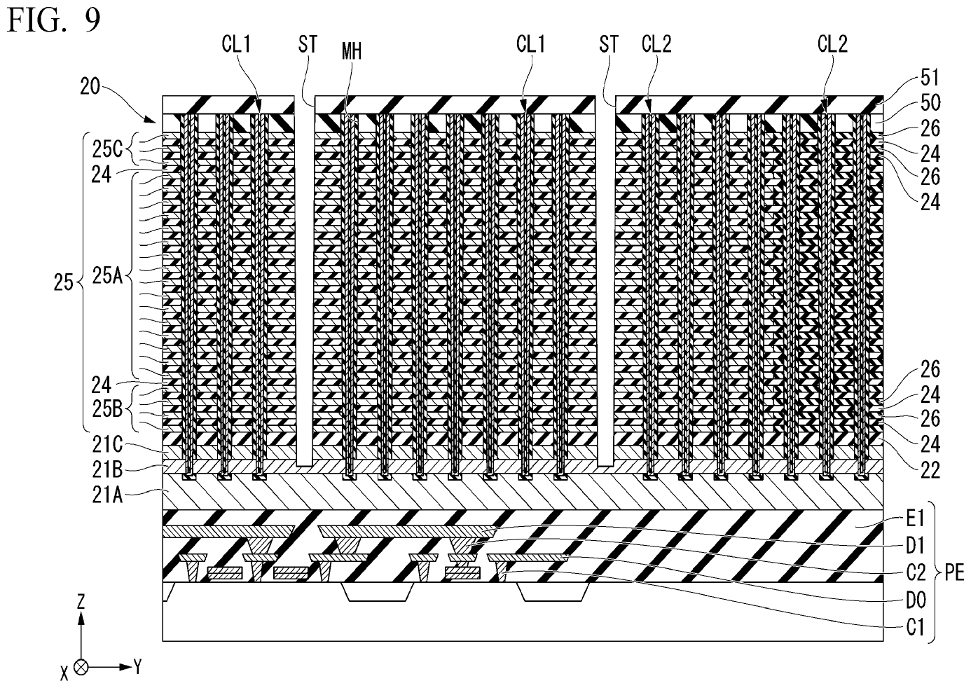

Next, as shown in FIG. 9, the memory hole MH is formed in the stack 20 shown in FIG. 8A. The memory hole MH extends from the upper surface of the stack 20 up to the middle of the semiconductor layer 21A. The memory hole MH is formed using etching. For example, anisotropic etching is performed from the upper surface of the stack 20 to the semiconductor layer 21A. Meanwhile, the memory hole MH is an example of a “hole.”

Anisotropic etching is performed using, for example, a gas G containing a carbon element and a fluorine element. The gas G includes, for example, CₓH_{y}F_{z} gas. Here, C represents carbon, H represents hydrogen, F represents fluorine, x is an integer equal to or greater than 1, y is an integer equal to or greater than 0, and z is an integer equal to or greater than 1 (x≥1, y≥0, z≥1). In the case of y=0, CₓH_{y}F_{z} is fluorocarbon, and in the case of y≠0, CₓH_{y}F_{z} is hydrofluorocarbon. The CₓH_{y}F_{z} gas is, for example, C₄F₆ gas, C₄F₈ gas, CH₂F₂ gas, or the like.

In the above etching process, etching is performed using CₓH_{y}F_{z} plasma generated from the CₓH_{y}F_{z} gas, and sidewall films are formed on the surfaces of the insulating film 24, the insulating film 26a, and the like exposed in the memory hole MH. The sidewall film is, for example, a fluorocarbon film (CF film) containing a carbon element and a fluorine element. However, in the manufacturing method of the present embodiment, since the insulating film 26b containing hydrogen and/or oxygen is provided on the insulating film 26a, the CF film is not likely to adhere to the surface of the insulating film 26a exposes to the memory hole MH during the above etching process. As a result, the amount of SiN chipping (size) can be reduced in the entire stack 20.

Next, the memory stacked film 62, the semiconductor layer 61, and the insulating core 60 are formed in this order within the memory hole MH. The memory hole MH is filled with the memory stacked film 62, the semiconductor layer 61, and the insulating core 60. Thereby, the first pillar CL1 and the second pillar CL2 are formed in the memory hole MH. Annealing treatment may be appropriately performed on the first pillar CL1 and the second pillar CL2.

Next, the cover insulating layer 51 is formed on the stack 20 where the first pillar CL1 and the second pillar CL2 are formed. Thereafter, a plurality of slits ST are formed in the stack 20. The slit ST is a deep slit and extends from the upper surface of the stack 20 up to the middle of the sacrificial film 21Bb. The slit ST is formed using anisotropic etching. A stopper film is formed on the inner wall of the slit ST. The stopper film is, for example, a silicon oxide.

Next, the sacrificial film 21Bb is isotropically etched through the slit ST. The sacrificial film 21Bb is removed using isotropic etching. The isotropic etching is performed using an etchant with which a silicon nitride can be etched faster than a silicon oxide. In addition, a portion of the memory stacked film 62 is also removed by further etching. A portion of the memory stacked film 62 exposed by removing the sacrificial film 21Bb is removed. A portion of the semiconductor layer 61 is exposed by removing a portion of the memory stacked film 62. The memory stacked film 62 is etched using an etchant with which a silicon oxide can be etched faster than a silicon nitride. In etching the memory stacked film 62, the intermediate films 21Ba and 21Bc and the stopper film are also removed simultaneously with the memory stacked film 62. A space is formed between the semiconductor layer 21A and the semiconductor layer 21C.

Next, as shown in FIG. 9, the space is filled with a semiconductor material through the slit ST to form the semiconductor layer 21B. Thereby, the semiconductor layer 61 and the semiconductor layer 21B which are exposed are brought into contact with each other. The material of the semiconductor layer 21B is as described above. The semiconductor layer 21B contains, for example, phosphorus.

Next, as shown in FIG. 9, the insulating film 26a and the insulating film 26b are replaced with the conductive film 25 (25A, 25B, 25C). First, the insulating film 26a and the insulating film 26b are removed through the slit ST. The insulating film 26a and the insulating film 26b are removed using isotropic etching. The isotropic etching uses an etchant with which a silicon nitride can be etched faster than a silicon oxide and polysilicon. However, in this case, since the etchant does not reach (is not influenced by) a portion of the end region EA, the insulating film 26a and the insulating film 26b which are sacrificial films remain without being removed. That is, the insulating film 26a and the insulating film 26b are not replaced with the conductive film 25. That is, the end region EA in which the insulating film 26a and the insulating film 26b are not replaced with the conductive film 25 is the non-replaced region EA2 shown in FIG. 4.

Thereafter, the portions from which the insulating film 26a and the insulating film 26b are removed are filled with a conductive material to form the conductive layer (25A, 25B, 25C). Thereby, the first stack 20A and the second stack 20B are formed.

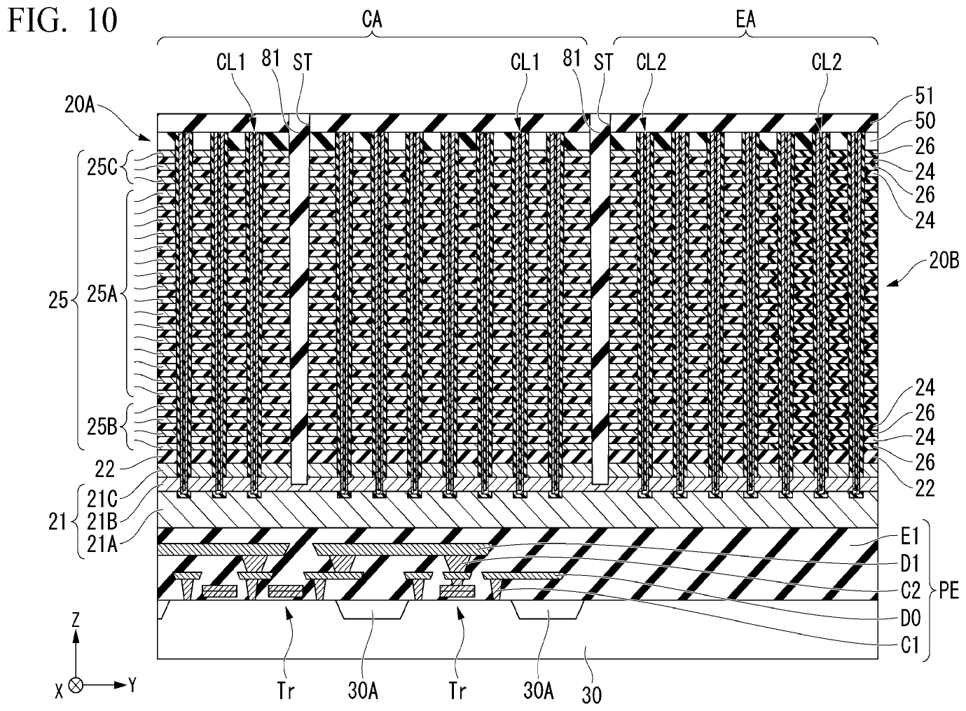

Next, as shown in FIG. 10, the slit ST is filled with an insulator to form the first separation portion 81. Thereby, the cell array region CA and the end region EA are divided in the Y direction.

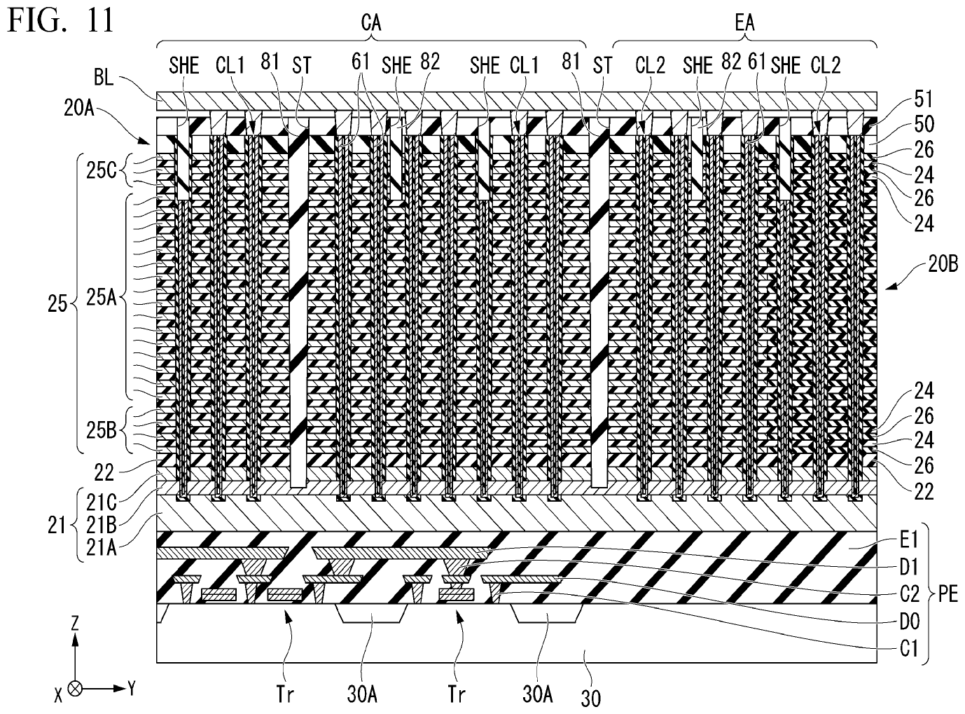

Next, as shown in, FIG. 11, a plurality of slits SHE are formed. The plurality of slits SHE all extend from at least the upper surfaces of the first stack 20A and the second stack 20B to a depth corresponding to the third conductive layer 25C (the drain-side selection gate line SGD). The plurality of slits SHE are formed using etching. For example, anisotropic etching is performed from the upper surfaces of the first stack 20A and the second stack 20B to a depth corresponding to the third conductive layer 25C (the drain-side selection gate line SGD). The anisotropic etching is, for example, reactive ion etching (RIE). Next, the plurality of slits SHE are filled with an insulator to form the second separation portion 82.

Next, the bit line BL is provided above the first stack 20A and the second stack 20B.

The semiconductor memory device 1 of the present embodiment is formed through the above steps. Meanwhile, the manufacturing steps are an example, and other steps may be inserted between the steps.

### 3. Modification Example of Embodiment

Next, a modification example of the embodiment will be described.

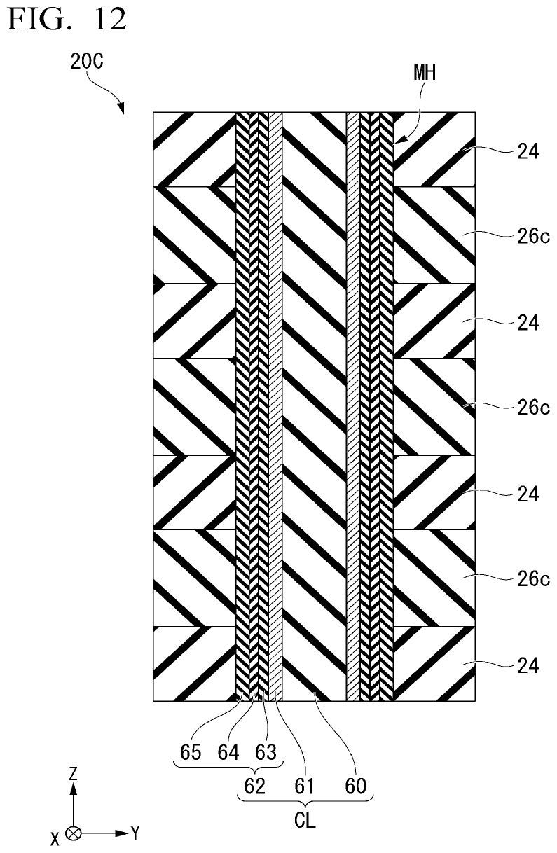

FIG. 12 is a cross-sectional view illustrating a portion of the end region EA of the semiconductor memory device 1A of the present modification example.

The present modification example has a third stack 20C in the end region EA. The third stack 20C in the end region EA differs from that of the present embodiment in that the insulating film 24 and an insulating film 26c containing nitrogen and oxygen or hydrogen are alternately stacked. That is, in the present embodiment, the insulating film 26b containing oxygen or hydrogen (for example, a silicon nitride film containing oxygen or hydrogen) is provided on the insulating film 26b containing a silicon nitride (for example, a silicon nitride film), whereas in the present modification example, the insulating film 26c containing oxygen or hydrogen is provided between all the insulating films 24 adjacent to each other. Meanwhile, the “insulating film 26c” is an example of a second insulating film and has the same film composition as the insulating film 26b.

The configurations of the present modification example other than those to be described below are the same as the configurations of the present embodiment.

The third stack 20C in the present modification example has a plurality of insulating films 24 and a plurality of insulating films 26c in the Z direction. The insulating film 24 and the insulating film 26c are alternately stacked in this order in the Z direction. The plurality of insulating films 26c spread in the X direction and the Y direction.

The plurality of insulating films 26c spread in the X direction and the Y direction. That is, each of the insulating films 26c is formed in a plate shape spread in the X direction and the Y direction. The insulating film 26c is provided between the insulating films 24 adjacent to each other in the Z direction. That is, the third stack 20C in the end region EA is configured with the insulating film 24 and the insulating film 26c alternately stacked in the Z direction. The insulating film 26c contains, for example, a silicon nitride and further contains oxygen or hydrogen. The number of layers of the insulating film 26c is determined by the number of layers of the insulating film 24, and may be the same as, for example, the number of layers of the insulating film 24.

Similarly to the insulating film 26b of the present embodiment, the plurality of insulating films 26c have a function of preventing carbon fluoride derived from the etching gas from adhering to the sidewall in the memory hole MH and depositing as a CF film during the formation of the memory hole MH.

The average hydrogen concentration of the insulating film 26c is more than 15 atom %. By containing hydrogen in the insulating film 26c containing a silicon nitride (SiN), it is possible to prevent carbon fluoride (CF) from adhering to the sidewall in the memory hole MH during the formation of the memory hole MH. As a result, it is possible to reduce the amount of SiN chipping (that is, chipping size) that has occurred in the memory cell array of the comparative example. When the amount of SiN chipping exceeds a certain level, the variation in drive voltage increases, which may lead to instability of electrical characteristics. However, by setting the average hydrogen concentration of the insulating film 26c to be equal to or more than 15 atom %, it is possible to reduce the amount of SiN chipping and to stabilize the electrical characteristics. In order to enjoy this effect more, it is preferable to set the average hydrogen concentration of the insulating film 26c to be equal to or more than 19 atom %.

In addition, oxygen can also be used instead of hydrogen as an element contained in the insulating film 26c. Even in a case where oxygen is contained in the insulating film 26c instead of hydrogen, the effect of containing hydrogen as described above can be achieved. In order to achieve the above effect, the average oxygen concentration in the insulating film 26c should be more than 17 atom %. Preferably, it is equal to or more than 17.7 atom %.

Meanwhile, both hydrogen and oxygen may be contained in the insulating film 26c. Even in that case, the above effect can be fully enjoyed. In a case where both hydrogen and oxygen are contained in the insulating film 26c, the total amount thereof is preferably equal to or more than 19 atom %.

The film thickness of each of the plurality of insulating films 26c is preferably equal to or more than 10 nm. In a case where the film thickness of the insulating film 26c is equal to or more than 10 nm, it is possible to stably prevent carbon fluoride (CF) from adhering to the sidewall in the memory hole MH during the formation of the memory hole MR. As a result, it is possible to reduce the amount of SiN chipping and to stabilize the electrical characteristics. The film thickness of each of the plurality of insulating films 26c is more preferably equal to or more than 0.5 nm. Although the upper limit of the film thickness of the insulating film 26c is not particularly limited from the viewpoint of the electrical characteristics, the film thickness of the insulating film 26c may be, for example, equal to or less than 40 nm.

According to the semiconductor memory device 1A of the present modification example, similarly to the present embodiment, it is possible to reduce the amount of SiN chipping and to, as a result, improve the electrical characteristics of the semiconductor memory device 1A. In addition, in the semiconductor memory device 1A of the present modification example, oxygen and/or hydrogen are contained inside the insulating film 26c provided on the insulating film 24. Therefore, it is possible to further enhance the effect of reducing the amount of SiN chipping.

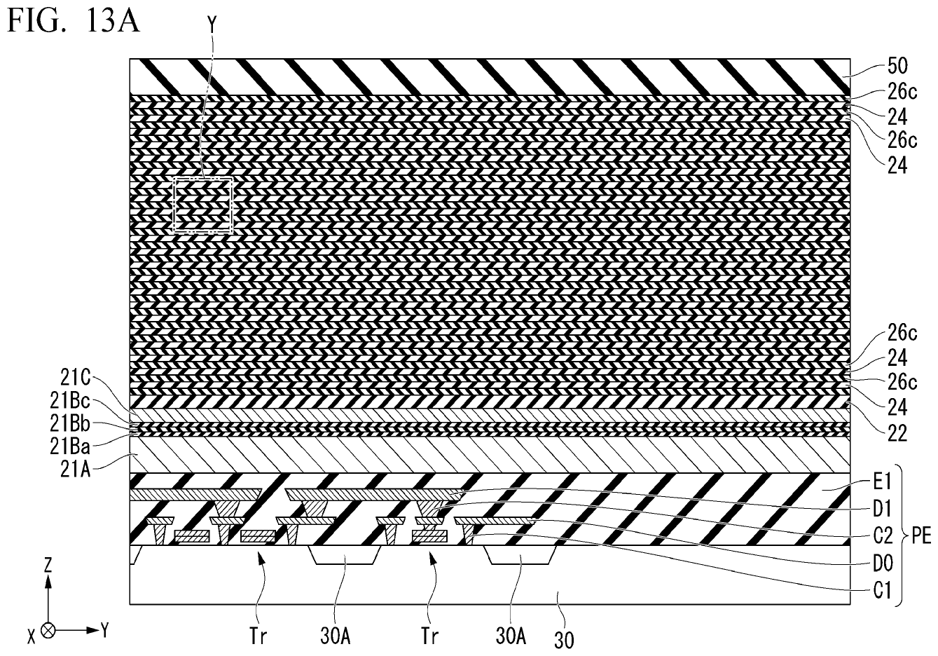

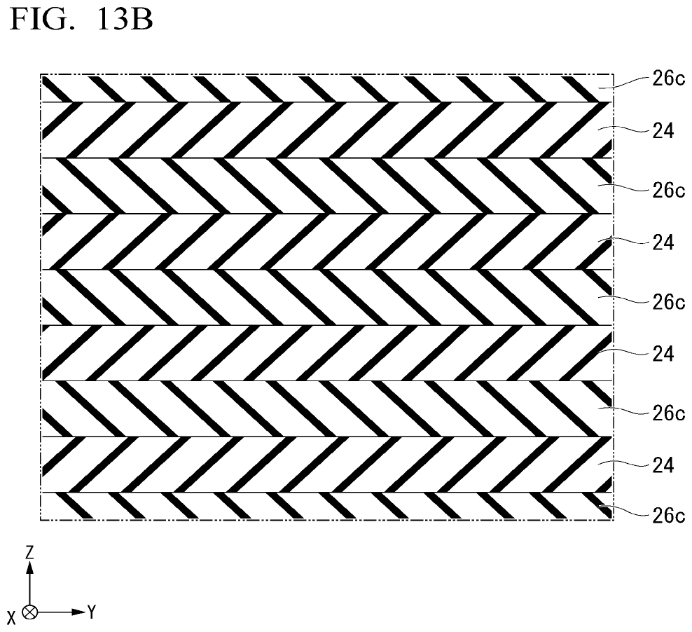

Next, a method of manufacturing the semiconductor memory device 1A which is a modification example of the present embodiment will be described. FIGS. 13A and 13B are cross-sectional views illustrating a method of manufacturing the semiconductor memory device 1 of the present embodiment. Meanwhile, FIG. 13B is an enlarged view of a region Y in FIG. 13A.

The difference between the method of manufacturing the semiconductor memory device 1A of the present modification example and the method of manufacturing the semiconductor memory device 1 of the present embodiment is that the insulating film 24 and the insulating film 26c are alternately stacked in the Z direction as shown in FIGS. 13A and 13B.

The insulating film 26c can be formed using plasma chemical vapor deposition (CDV) in the same way as the insulating film 26b. Specifically, in a case where hydrogen is contained in the insulating film 26c, for example, the hydrogen concentration in the insulating film 26c can be adjusted within the above range by adjusting one or more conditions of the flow rate of SiH₄ gas and the flow rate of NH gas. For example, in a case where the hydrogen concentration is desired to be increased, the flow rate of SiH₄ gas need only be increased. In addition, in a case where oxygen is contained in the insulating film 26c, the oxygen concentration in the insulating film 26c can be adjusted within the above range by adding N₂ O gas and adjusting its flow rate. In a case where both hydrogen and oxygen are contained in the insulating film 26c, the concentration of each element can be adjusted by appropriately combining the above conditions. Each step after the insulating film 24 and the insulating film 26c are alternately stacked is the same as the method of manufacturing the semiconductor memory device 1 of the above embodiment.

According to the method of manufacturing the semiconductor memory device 1A of the present modification example, the insulating film 26c which is a silicon nitride containing oxygen and/or hydrogen is disposed on the insulating film 24. Since the wet etching rate of a silicon nitride containing oxygen and/or hydrogen is higher than that of a silicon nitride, it is possible to improve the efficiency of processing when the insulating film 26c is replaced with a conductive layer.

Hereinbefore, although several embodiments have been described, the embodiment is not limited to the above examples. For example, the memory film may be a ferroelectric film included in a ferroelectric FET (FeFET) memory that stores data according to the direction of polarization. The ferroelectric film is formed of, for example, a hafnium oxide.

While several embodiments of the present invention have been described, these embodiments have been presented by way of example only, and are not intended to limit the scope of the invention. Indeed, these embodiments described herein may be embodied in a variety of other forms, and furthermore, various omissions, substitutions and changes in the form of the embodiments described herein may be made without departing from the spirit of the present invention. The appended claims and their equivalents are intended to cover such forms or modifications as would fall within the scope and spirit of the present invention.

What is claimed is:

1. A semiconductor memory device comprising:
a multi-layered structure having a first region and a second region;
the first region of the multi-layered structure comprising a first stack and a first pillar;
the first stack comprising an alternate stack in a first direction of a plurality of first insulating films containing oxygen and a plurality of first conductive films;
the first pillar comprising a first semiconductor layer and extending in the first direction;
the second region of the multi-layered structure comprising a second stack and a second pillar;
the second stack comprising a repeated stack in the first direction of the plurality of first insulating films containing oxygen, a plurality of second insulating films containing nitrogen, and a plurality of third insulating films containing nitrogen and at least one of oxygen and hydrogen, the repeated stack being in the order of the first, second and third insulating films,
the second pillar comprising a second semiconductor layer and extending in the first direction;
the first and second regions are adjacent each other in a second direction intersecting the first direction.

2. The semiconductor memory device according to claim 1, wherein an average hydrogen concentration of the plurality of third insulating films is more than 15 atom %.

3. The semiconductor memory device according to claim 1, wherein an average oxygen concentration of the plurality of third insulating films is more than 5 atom %.

4. The semiconductor memory device according to claim 1, wherein a film thickness of each of the plurality of third insulating films is equal to or more than 1 nm.

5. The semiconductor memory device according to claim 1, wherein a film thickness of each of the plurality of first insulating films is equal to or less than 20 nm, and a film thickness of each of the second insulating films is equal to or less than 30 nm.

6. The semiconductor memory device according to claim 1, wherein a film thickness of each of the first insulating films is equal to or more than 10 nm and equal to or less than 20 nm, and a film thickness of each of the second insulating films is equal to or more than 10 nm and equal to or less than 30 nm.

7. The semiconductor memory device according to claim 1, further comprising:
a first insulator penetrating through the first stack in the first direction and extending in a third direction intersecting the first direction and the second direction, wherein
the first insulator isolating the first region and the second region from each other, and the first insulator being between the first region and the second region.

8. A semiconductor memory device comprising:
a multi-layered structure having a first region and a second region;
the first region of the multi-layered structure comprising a first stack and a first pillar;
the first stack comprising an alternate stack in a first direction of a plurality of first insulating films containing oxygen and a plurality of first conductive films;
the first pillar comprising a first semiconductor layer and extending in the first direction;
the second region of the multi-layered structure comprising a second stack and a second pillar;
the second stack comprising an alternate stack in the first direction of the plurality of first insulating films containing oxygen, and a plurality of second insulating films containing nitrogen and at least one of oxygen and hydrogen;
the second pillar comprising a second semiconductor layer and extending in the first direction;
the first and second regions are adjacent each other in a second direction intersecting the first direction.

9. The semiconductor memory device according to claim 8, wherein an average hydrogen concentration of the plurality of second insulating films is more than atom %.

10. The semiconductor memory device according to claim 8, wherein an average oxygen concentration of the plurality of second insulating films is more than 17 atom %.

11. The semiconductor memory device according to claim 8, wherein a total amount of hydrogen and oxygen of the plurality of second insulating films is more than 19 atom %.

12. The semiconductor memory device according to claim 8, wherein a film thickness of each of the plurality of second insulating films is equal to or more than 10 nm.

13. The semiconductor memory device according to claim 8, wherein a film thickness of each of the plurality of first insulating films is equal to or more than 10 nm and equal to or less than 40 nm.

14. A method of forming a semiconductor device, the method comprising:
repeatedly stacking, in a first direction, a plurality of first insulating films containing oxygen, a plurality of second insulating films containing nitrogen, and a plurality of third insulating films containing nitrogen and at least one of oxygen and hydrogen, in the order of the first, second and third insulating films, to form an insulator stack of the first, second and third insulating films; and
dry-etching the insulator stack using an etching gas containing carbon and fluorine, to form a hole extending in the first direction in the insulator stack.

15. The method according to claim 14, wherein an average hydrogen concentration of the plurality of third insulating films is more than 15 atom %.

16. The method according to claim 14, wherein an average oxygen concentration of the plurality of third insulating films is more than 5 atom %.

17. The method according to claim 14, wherein a film thickness of each of the plurality of third insulating films is equal to or more than 1 nm.

18. The method according to claim 14, wherein a film thickness of each of the plurality of first insulating films is equal to or less than 20 nm, and a film thickness of each of the second insulating films is equal to or less than 30 nm.

19. The method according to claim 14, wherein a film thickness of each of the first insulating films is equal to or more than 10 nm and equal to or less than 20 nm, and a film thickness of each of the second insulating films is equal to or more than 10 nm and equal to or less than 30 nm.
